(19) United States
(12) Patent Application Publication
(10) Pub. No.: US 2025/0072248 A1
(43) Pub. Date: Feb. 27, 2025

(54) FANOUT LINES AND DISPLAY DEVICE HAVING THE SAME

(71) Applicant: Samsung Display Co., Ltd., Yongin-si (KR)

(72) Inventor: GYU-TAE KIM, Yongin-si (KR)

(21) Appl. No.: 18/675,436

(22) Filed: May 28, 2024

(30) Foreign Application Priority Data
Aug. 23, 2023 (KR) 10-2023-0110412

(51) Int. Cl. H10K 59/131; H10K 59/88

(52) U.S. Cl. CPC H10K 59/1315; H10K 59/88

(57) ABSTRACT

A display device includes a display region including pixels and a non-display region which is adjacent to the display region, fanout lines in the non-display region, and signal lines which are in the display region and connect the pixels in the display region to the fanout lines in the non-display region. The fanout lines include first fanout wires spaced apart from each other along the non-display region at a first interval, at least one of the first fanout wires being disconnected along a length thereof to define an opening of the first fanout wires, and second fanout wires respectively extending from the first fanout wires and spaced apart from each other along the non-display region at a second interval greater than the first interval.

This patent application claims priority to Korean Patent Application No. 10-2023-0110412, filed on Aug. 23, 2023, and all the benefits accruing therefrom under 35 U.S.C. § 119, the entire contents of which are hereby incorporated by reference.

### BACKGROUND

### (1) Field

The disclosure herein relates to a display device. More particularly, the invention herein relates to a display device with improved reliability.

### (2) Description of the Related Art

A display device provides information to outside the display device, such as to a user, by displaying various images on a display screen of the display device. In general, a display device displays information within an allocated display screen.

A display device includes a display region for displaying information and a non-display region which surrounds the display region. A number of signal lines are disposed in the non-display region of the display device, and may affect a panel size and/or a resolution of the display device.

### SUMMARY

As a size of a display device is larger, the number of signal lines in a non-display region of the display device becomes greater so as to achieve an increased panel size and high resolution. However, the increase of the number of the signal lines causes the electrical resistance values of such signal lines to be increased and image quality of a display image to be deteriorated. Therefore, a display device is desired which reduces the electrical resistance values of signal lines to secure scan times for respective signal lines and improve display quality.

The disclosure provides a display device with excellent display quality and improved aesthetics by reducing a bezel region.

An embodiment of the invention provides a display device including a display region including pixels and a non-display region which is adjacent to the display region, fanout lines in the non-display region and signal lines which are in the display region and connect the pixels in the display region to the fanout lines in the non-display region where the fanout lines includes first fanout wires spaced apart from each other along the non-display region at a first interval, at least one of the first fanout wires being disconnected along a length thereof to define an opening of the first fanout wires, and second fanout wires respectively extending from the first fanout wires and spaced apart from each other along the non-display region at a second interval greater than the first interval.

In an embodiment, the first fanout wires may include a connection wire connected to a signal line among the signal lines and a dummy wire which is adjacent to the connection wire and not connected to the signal line.

In an embodiment, the dummy wire may be disconnected along a length thereof to define the opening of the first fanout wire.

In an embodiment, among the first fanout wires in the non-display region, the dummy wire which defines the opening may be an outermost first fanout wire.

In an embodiment, within the non-display region, the first fanout wires may include first connection wires and second connection wires alternating with each other and the first connection wires and the second connection wires in different layers from each other along a thickness direction of the non-display region.

In an embodiment, In an embodiment, the display device further includes a base layer in the display region and in the non-display region, and a first insulating layer and a second insulating layer on the base layer where the base layer, the first insulating layer, the first connection wires, the second insulating layer and the second connection wires are in order along the thickness direction of the non-display region.

In an embodiment, the first connection wires may include a first sub-connection wire connected to a first signal line among the signal lines and a first dummy wire which is adjacent to the first sub-connection wire and not connected to the signal lines, and the second connection wires may include a second sub-connection wire connected to a second signal line among the signal lines and a second dummy wire which is adjacent to the second sub-connection wire and not connected to the signal lines

In an embodiment, within the non-display region, the opening may be provided in plural including openings of the first fanout wires, the first dummy wire is disconnected along a length thereof to define a first opening among the openings of the first fanout wires, and the second dummy wire is disconnected along a length thereof to define a second opening among the openings of the first fanout wires.

In an embodiment, a width direction of the first fanout wires may cross the lengths of the first dummy wire and the second dummy wire, and the first opening may not overlap the second opening along the width direction.

In an embodiment, a width direction of the first fanout wires may cross the lengths of the first dummy wire and the second dummy wire, the first dummy wire may be provided in plural including first dummy wires on opposing sides of the first sub-connection wire along the width direction, and the first opening may be defined in each of the first dummy wires, the first openings overlapping along the width direction with the first sub-connection wire therebetween.

In an embodiment, a width direction of the first fanout wires may cross the lengths of the first dummy wire and the second dummy wire, the second dummy wire may be provided in plural including second dummy wires on opposing sides of the second sub-connection wire along the width direction, and the second opening may be defined in each of the second dummy wires, the second openings overlapping along the width direction with the second sub-connection wire therebetween.

In an embodiment, the first fanout wires may be spaced apart from each other along a first width direction and each have a first width along the first width direction, and the second fanout wires may be spaced apart from each other along a second width direction and each have a second width along the second width direction which is different from the first width.

In an embodiment, the first width and the second width may be respectively constant along respective lengths of the first fanout wires and the second fanout wires, and the second width of the second fanout wires may be greater than the first width of the first fanout wires.

In an embodiment, the non-display region may include a bending region at which the display device is bendable, the first fanout wires may be between the bending region and the display region, and the second fanout wires may be on the bending region.

In an embodiment of the invention, a display device may include a display region including pixels and a non-display region which is adjacent to the display region, fanout lines in the non-display region and signal lines which are in the display region and connect the pixels in the display region to the fanout lines in the non-display region where the fanout lines include first connection wires of a first conductive layer which are connected to first signal lines among the signal lines, second connection wires of a second conductive layer on the first conductive layer, the second connection wires connected to second signal lines among the signal lines, and a connection wire among the first connection wires and the second connection wires being disconnected along a length thereof to define an opening of the fanout lines.

In an embodiment, along the non-display region, the first connection wires and the second connection wires may alternate with each other and be spaced apart from each other.

In an embodiment, the first connection wires may include a first sub-connection wires connected to the first signal lines, and a first dummy wires not connected to the signal lines, and the second connection wires may include a second sub-connection wires connected to the second signal lines, and a second dummy wires not connected to the signal lines.

In an embodiment, within the non-display region, the opening may be provided in plural including openings of the fanout lines, a first connection wire is disconnected along a length thereof to define a first opening among the openings of the fanout lines, and a second connection wire is disconnected along a length thereof to define a second opening among the openings of the fanout lines.

In an embodiment, the fanout wiring may include a first fanout wires spaced apart from each other along the non-display region at a first interval, and second fanout wires respectively extending from the first fanout wires and spaced apart from each other along the non-display region, at a second interval greater than the first interval, and at least one of the first fanout wires may be disconnected along a length thereof to define the opening of the fanout lines.

In an embodiment, the non-display region may include a bending region at which the display device is bendable, the first fanout wires may be between the bending region and the display region, and the second fanout wires may be on the bending region.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device according to an embodiment of the invention;

FIG. 2A is an exploded perspective view of a display device according to an embodiment of the invention;

FIG. 2B is an exploded perspective view of a display device according to an embodiment of the invention;

FIG. 3 is a cross-sectional view of a display module according to an embodiment of the invention;

FIG. 4 is a plan view of a partial configuration included in a display module according to an embodiment of the invention;

FIG. 5 is a enlarged cross-sectional view of a display panel according to an embodiment of the invention;

FIG. 6 is an enlarged plan view of region AA′ illustrated in FIG. 4;

FIG. 7A is a cross-sectional view taken along line I-I′ illustrated in FIG. 6;

FIG. 7B is a cross-sectional view taken along line II-II′ illustrated in FIG. 6;

FIG. 7C is an enlarged view of region BB′ of FIG. 6;

FIG. 8A is an enlarged plan view of a portion of a display panel according to an embodiment of the invention;

FIG. 8B is an enlarged view of region CC′ of FIG. 8A;

FIG. 8C is a cross-sectional view taken along line III-III′ illustrated in FIG. 8B;

FIG. 9A is a view illustrating a display panel and a tag part according to an embodiment of the invention; and

FIG. 9B is an enlarged view of region DD′ illustrated in FIG. 9A.

### DETAILED DESCRIPTION

The invention may be implemented in various modifications and have various forms, and specific embodiments are illustrated in the drawings and described in detail in the text. It is to be understood, however, that the invention is not intended to be limited to the particular forms disclosed, but on the contrary, is intended to cover all modifications, equivalents, and alternatives falling within the spirit and scope of the invention.

In this specification, it will be understood that when an element (or region, layer, portion, or the like) is referred to as being related to another element such as being “on”, “connected to” or “coupled to” another element, it may be directly disposed/connected/coupled to another element, or intervening elements may be disposed therebetween. In contrast, when an element (or region, layer, portion, or the like) is referred to as being related to another element such as being “directly on”, “directly connected to” or “directly coupled to” another element, no intervening element is disposed therebetween.

Like reference numerals or symbols refer to like elements throughout. Also, in the drawings, the thickness, the ratio, and the dimension of the elements are exaggerated for effective description of the technical contents. Within the Figures and the text of the disclosure, a reference number indicating a singular form of an element may also be used to reference a plurality of the singular element.

The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the invention.

The terminology used herein is for the purpose of describing particular embodiments only and is not intended to be limiting. The singular forms include the plural forms as well, unless the context clearly indicates otherwise. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.”

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, embodiments of the invention will be described with reference to the accompanying drawings.

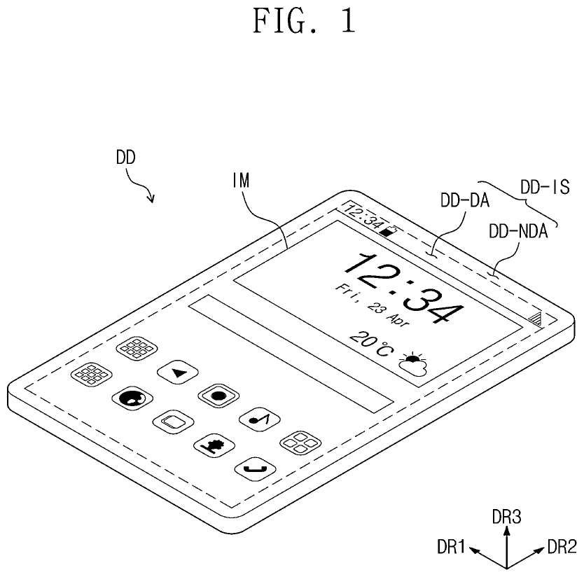

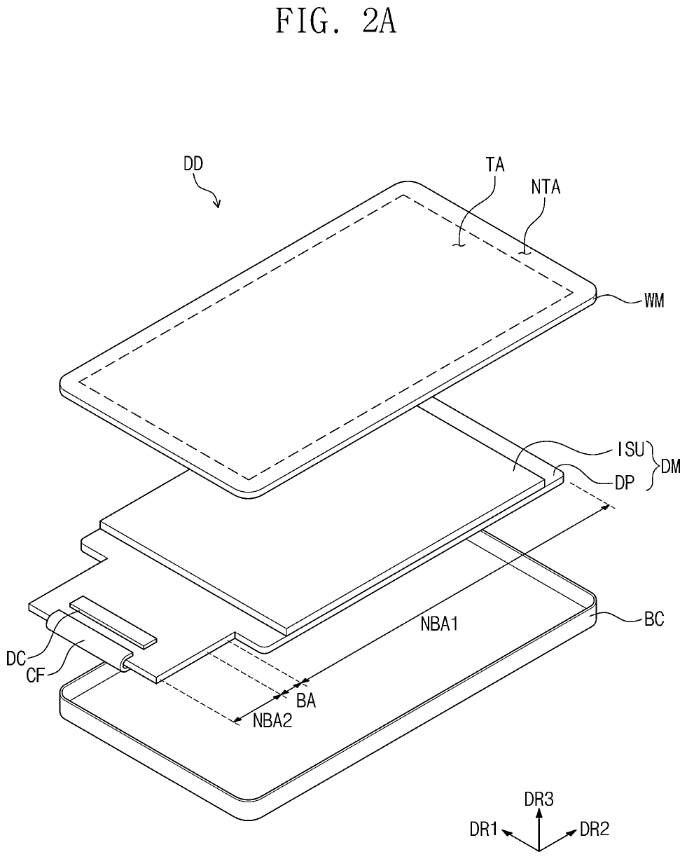

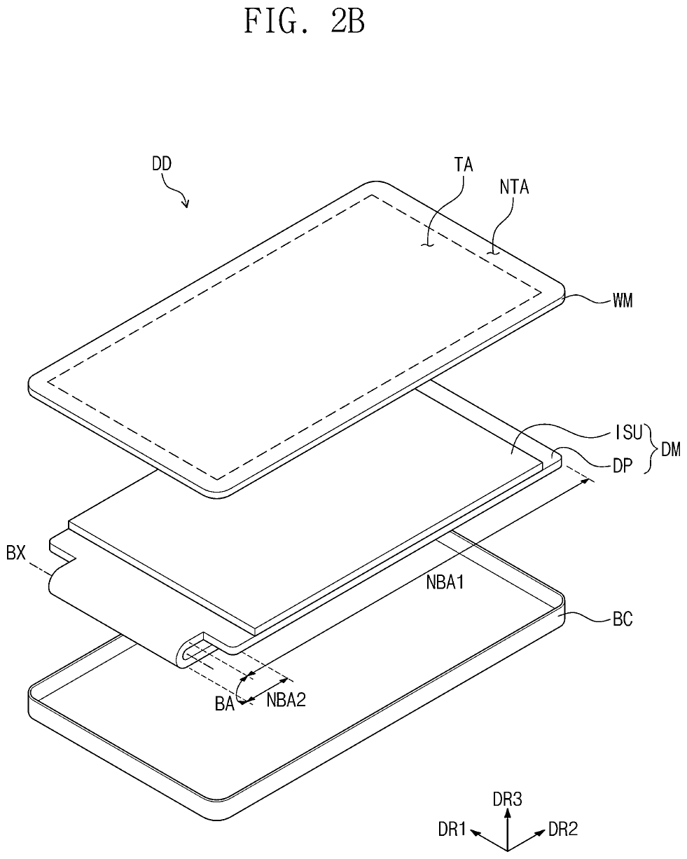

FIG. 1 is a perspective view of a display device DD according to an embodiment of the invention. FIGS. 2A and 2B are exploded perspective views of a display device DD according to an embodiment of the invention. FIG. 2B illustrates a state where a display panel DP of a display device DD is bent. In this specification, the display device DD is exemplarily illustrated as a cellular phone terminal. The display device DD according to the invention may be applied to a small-sized and medium-sized electronic device such as a tablet computer, a car navigation system, a game console, and a smart watch, as well as a large-sized electronic device such as a television and a monitor.

Referring to FIG. 1, the display device DD of an electronic device may display an image IM through a display surface DD-IS. Icon images are exemplarily illustrated as the image IM. The display surface DD-IS is parallel to a plane defined by a first direction DR1 and a second direction DR2 crossing each other. A normal direction relative to the display surface DD-IS, that is, a thickness direction of the display device DD, is indicated by a third direction DR3 which crosses each of the first and second directions DR1 and DR2.

The display surface DD-IS includes a display region DD-DA in which the image IM is displayed, and a non-display region DD-NDA adjacent to the display region DD-DA. The non-display region DD-NDA is a region (or planar area) in which an image IM is not displayed. However, an embodiment of the invention is not limited thereto, and the non-display region DD-NDA may be adjacent to any one or more side of the display region DD-DA or may be omitted.

In this specification, the wording “when viewed on a plane” or “on a plane” may mean a case when viewed in (or along) the third direction DR3. A front surface (or upper surface) and a rear surface (or lower surface) of the display device DD or a layer or unit therein to be described below are defined based on the third direction DR3. However, combinations of the first to third directions DR1, DR2, and DR3 may be changed to other combinations thereof.

Referring to FIGS. 2A and 2B, the display device DD may include a window WM, a display module DM, and an accommodation member BC.

The window WM may be disposed above the display module DM, and transmit, to the outside, an image IM provided from the display module DM. The window WM includes a transmission region TA and a non-transmission region NTA. The transmission region TA may overlap the display region DD-DA illustrated in FIG. 1, and have a shape (e.g., planar shape) corresponding to that of the display region DD-DA. The window WM may include a base layer and functional layers which are disposed on the base layer. The functional layers may include a protective layer, an anti-fingerprint layer, and the like. The base layer of the window WM may be composed of or include glass, sapphire, plastic, or the like. The base layer of the window WM may include an optically transparent insulating material. For example, the base layer of the window WM may include glass or plastic. The base layer of the window WM may have a multi-layered structure or a single-layered structure. For example, the base layer of the window WM may include a plurality of plastic films, bonded via an adhesive agent, or may include a glass substrate and a plastic film which are bonded via an adhesive agent.

The non-transmission region NTA may overlap the non-display region DD-NDA and have a shape corresponding to that of the non-display region DD-NDA. The non-transmission region NTA may be a region having a relatively lower light transmittance than the transmission region TA. The non-transmission region NTA may be defined by disposing a bezel pattern in a partial region of the base layer of the window WM, and the transmission region TA may be defined as a region in which the bezel pattern is not disposed (e.g., except for or excluding the bezel pattern along a planar direction). However, the idea of the invention is not limited thereto, and the non-transmission region NTA may be omitted.

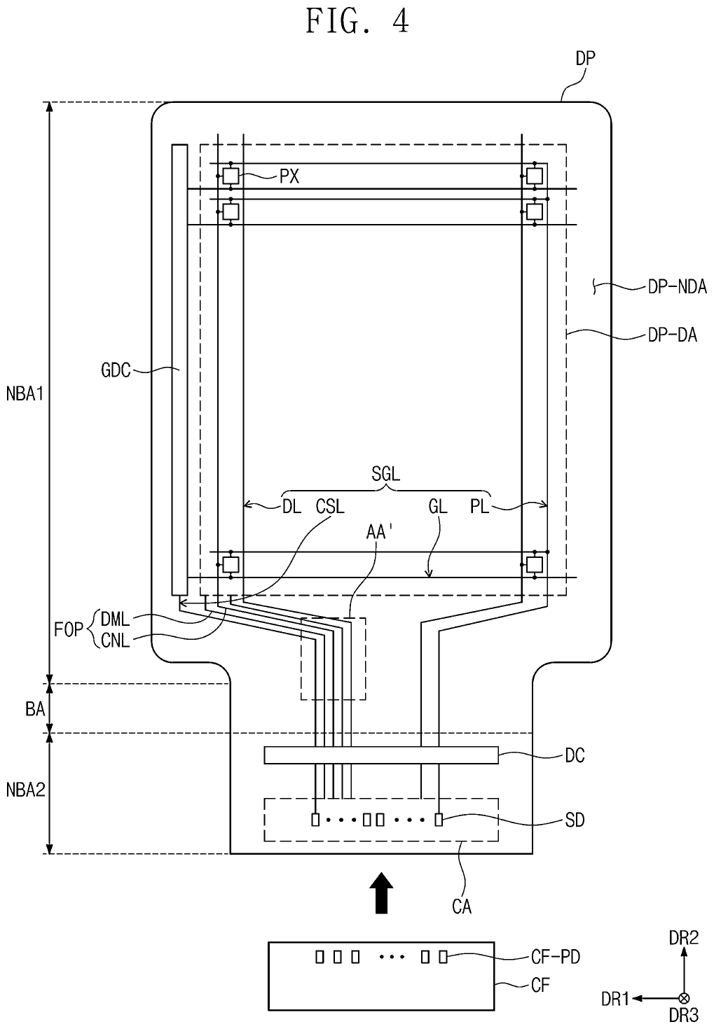

Although not illustrated, an anti-reflection layer may be disposed between the window WM and the display module DM, along the thickness direction. The anti-reflection layer may reduce reflectance for external light incident from the outside of the display device DD. The anti-reflection layer may include color filters. The color filters may have a predetermined arrangement. For example, the color filters may be arranged in consideration of light-emitting colors of pixels PX (see FIG. 4) included in a display panel DP to be described later. Additionally, the anti-reflection layer may further include a black matrix adjacent to the color filters.

According to an embodiment of the invention, the display module DM may include the display panel DP and an input sensor ISU as an input sensing layer.

The display panel DP may be any one among a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel. However, the display panel DP is not particularly limited thereto. Hereinafter, the display panel DP may be described as an organic light-emitting display panel.

The input sensor ISU may include any one among a capacitive sensor, an optical sensor, an ultrasonic sensor, and an electromagnetic induction sensor. The input sensor ISU may be formed or provided on the display panel DP through a continuous process, or may be manufactured separately and then attached to an upper side of the display panel DP via an intervening element such as an adhesive layer, but is not limited to any one embodiment.

The display module DM may include a printed circuit board CF and a driver integrated circuit DC. Although not illustrated, a main circuit board may be disposed on one side of the printed circuit board CF, such a a side opposite to the display panel DP. The printed circuit board CF may electrically connect the display panel DP and the main circuit board to each other. FIG. 2A illustrates that the driver integrated circuit DC is mounted on the display panel DP, but an embodiment of the invention is not limited thereto. The driver integrated circuit DC may generate a driving signal as an electrical signal used for an operation of the display panel DP on the basis of a control signal as an electrical signal transmitted from the printed circuit board CF.

The display panel DP may include a bending region BA, and a non-bending region provided in plural including, for example, a first non-bending region NBA1 and a second non-bending region NBA2 which are arranged to be spaced apart from each other in the second direction DR2 with the bending region BA therebetween.

The bending region BA may be defined as a region in which or at which the display panel DP is bendable with respect to an imaginary bending axis BX extending in the first direction DR1. The first non-bending region NBA1 may be defined as a region overlapping the transmission region TA, and the second non-bending region NBA2 may be defined as a region at which the printed circuit board CF is connected to the display panel DP. When the bending region BA of the display panel DP is bent with respect to the bending axis BX, the printed circuit board CF and the driver integrated circuit DC may be disposed below a rear surface of the display panel DP. Although not illustrated, additional components may be disposed at the rear surface to compensate for a step which is caused by the bending region BA and formed between the printed circuit board CF and a rear surface of the display panel DP.

According to an embodiment, in (or along) the second direction DR2, the width of the first non-bending region NBA1 may be greater than the widths of the bending region BA and the second non-bending region NBA2. However, an embodiment of the invention is not limited thereto, and the bending region BA may be provided in a planar shape such that the width of the bending region BA in the second direction DR2 becomes narrower from the first non-bending region NBA1 toward the second non-bending region NBA2. The bending region BA is not limited to any one embodiment.

As illustrated in FIG. 2B, a portion of the display panel DP is bent, so that the printed circuit board CF electrically bonded to the display panel DP may be disposed on a rear surface of the display panel DP.

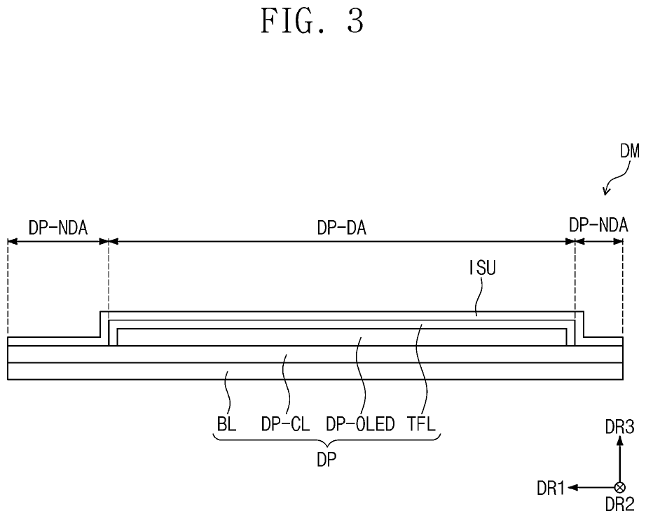

The accommodation member BC may accommodate the display module DM and be coupled to the window WM. The printed circuit board CF may be connected to the display panel DP at one end (e.g. a first end) of the display panel DP, such as being electrically connected to a circuit element layer DP-CL of the display panel DP (see FIG. 3). Although not illustrated, the display device DD may further include a main board, electronic modules which are mounted on the main board, a camera module, a power module, and the like.

The display device DD described above is exemplarily illustrated as a cellular phone terminal, but in this specification, the display device DD may include two or more electronic components electrically bonded to each other. The display panel DP and the driver integrated circuit DC which is mounted on the display panel DP respectively correspond to different electronic components, and the display device DD may be constituted by only these components. However, the constitution of the display device DD is not limited to any one embodiment.

In an embodiment, only the display panel DP and the printed circuit board CF which is connected to the display panel DP may constitute the display device DD, and only a main board and an electronic module which is mounted on the main board may constitute the display device DD. Hereinafter, the following description of the display device DD according to the invention will be mainly focused on a bonding structure of the display panel DP and the driver integrated circuit DC which is mounted on the display panel DP.

FIG. 3 is a cross-sectional view of a display module DM according to an embodiment of the invention. FIG. 4 is a plan view of a partial configuration included in a display module DM according to an embodiment of the invention.

Referring to FIG. 3, the display panel DP includes a base layer BL, a circuit element layer DP-CL disposed on the base layer BL, a display element layer DP-OLED, and an upper insulating layer TFL. An input sensor ISU may be disposed on the upper insulating layer TFL.

The display panel DP includes a display region DP-DA and a non-display region DP-NDA. The display region DP-DA of the display panel DP corresponds to the display region DD-DA illustrated in FIG. 2A and/or the transmission region TA illustrated in FIG. 2A, and the non-display region DP-NDA corresponds to the non-display region DD-NDA illustrated in FIG. 1 and/or the non-transmission region NTA illustrated in FIG. 2A. The non-display region DP-NDA may be referred to as a bezel region.

The base layer BL may include at least one plastic film. The base layer BL is a flexible substrate, and may include a plastic substrate, a glass substrate, a metal substrate, an organic/inorganic composite material substrate, or the like.

The circuit element layer DP-CL includes at least one of an intermediate insulating layer and/or a circuit element. The intermediate insulating layer includes at least one intermediate inorganic layer or at least one intermediate organic layer. The circuit element includes signal lines, a pixel driving circuit, and the like.

The display element layer DP-OLED includes a light emitting element provided in plural such as a plurality of organic light-emitting diodes. The display element layer DP-OLED may further include an organic layer such as a pixel-defining film PDL.

The upper insulating layer TFL seals the display element layer DP-OLED such as to provide an encapsulation layer. The upper insulating layer TFL may be disposed on the display element layer DP-OLED. The upper insulating layer TFL may overlap the display region DP-DA and the non-display region DP-NDA. The upper insulating layer TFL may overlap at least a portion of the non-display region DP-NDA. For example, the upper insulating layer TFL may include a thin-film encapsulation layer. The thin-film encapsulation layer may have a stacked structure of an inorganic layer/an organic layer/an inorganic layer. The upper insulating layer TFL protects the display element layer DP-OLED against moisture, oxygen, and foreign substances such as dust particles. However, an embodiment of the invention is not limited thereto, and the upper insulating layer TFL may further include an additional insulating layer in addition to a thin-film encapsulation layer. For example, an optical insulating layer for controlling a refractive index may be further included.

In an embodiment of the invention, an encapsulation substrate may be provided instead of the upper insulating layer TFL. In this case, the encapsulation substrate may face the base layer BL, and the circuit element layer DP-CL and the display element layer DP-OLED may be disposed between the encapsulation substrate and the base layer BL.

The input sensor ISU may be directly disposed on the display panel DP. In this specification, the wording, “an A component being directly disposed on a B component” means that another layer is not disposed between the A component and the B component. As being directly disposed, elements may be in contact with each other, such as forming an interface therebetween. In this embodiment, the input sensor ISU and the display panel DP may be manufactured or provided through a continuous process. However, the idea of the invention is not limited thereto, and the input sensor ISU may be provided as a separate panel and coupled to the display panel DP via the adhesive layer as a separate element. As another example, the input sensor ISU may be omitted.

Referring to FIG. 4, the display panel DP may include a plurality of pixels PX, a gate driving circuit GDC, a signal line provided in plural as a plurality of signal lines SGL, a fanout wiring provide in plural as a fanout wiring part FOP, and a display pad DP provided in plural as a plurality of display pads SD.

The pixels PX are disposed in the display region DP-DA. The pixels PX each include an organic light-emitting diode as a light emitting element and a pixel driving circuit which is connected thereto. The gate driving circuit GDC and the signal lines SGL may be included in the circuit element layer DP-CL illustrated in FIG. 3.

The gate driving circuit GDC sequentially outputs gate signals to a plurality of gate lines GL. The gate driving circuit GDC may include a plurality of thin-film transistors formed through the same process for layers or patterns of a driving circuit of the pixels PX, for example, a low temperature polycrystalline silicon (LTPS) process or a low temperature polycrystalline oxide (LTPO) process. The display panel DP may further include another driving circuit that provides a light-emitting control signal to the pixels PX.

The signal lines SGL include gate lines GL, data lines DL, a power line PL, and a control signal line CSL. The gate lines GL are respectively connected to corresponding pixels PX among the pixels PX, and the data lines DL are respectively connected to corresponding pixels PX among the pixels PX. The power line PL is connected to the pixels PX. The control signal line CSL may provide control signals to a scan driving circuit (not shown).

The signal lines SGL may be disposed in the display region DP-DA. The control signal line CSL among the signal lines SGL overlaps the non-display region DP-NDA. The fanout wiring part FOP may be disposed in the non-display region DP-NDA. The fanout wiring part FOP may be connected to a pad part to be described later to electrically connect the pad part in the non-display region DP-NDA and the signal lines SGL in the display region DP-DA, to each other.

The fanout wiring part FOP may include a connection wire CNL connected to the signal lines SGL and a dummy wire DML which is not connected to the signal lines SGL. The connection wire CNL may be electrically connected to at least one of the gate lines GL, the data lines DL, or the power line PL among the signal lines SGL in the display region DP-NDA, to electrically connect the at least one of these lines to the pad part in the non-display region DP-NDA, to be described later.

The display panel DP may include a plurality of display pads SD. The plurality of display pads SD may be disposed to be spaced apart from each other at a predetermined interval. The plurality of display pads SD according to an embodiment may be disposed to overlap the second non-bending region NBA2. The plurality of display pads SD may be disposed in a connection region CA of the second non-bending region NBA2. The connection region CA may be defined as an area (e.g., a connection area), of the second non-bending region NBA2, at which the display pads SD are disposed and at which the printed circuit board CF is attached to the display panel DP.

The display pads SD may be disposed to overlap the connection region CA. The driver integrated circuit DC may be mounted on the second non-bending region NBA2, and spaced apart from the connection area. The display pads SD may be electrically connected to the driver integrated circuit DC to transmit, to the signal lines SGL, an electrical signal received from the driver integrated circuit DC.

The printed circuit board CF may include board pads CF-PD at which the printed circuit board CF is electrically connected to the display panel DP. The board pads CF-PD may be arranged along the first direction DR1.

The display pads SD are electrically connected to the board pads CF-PD included in the printed circuit board CF to transmit, to the display panel DP, an electrical signal received from the printed circuit board CF. The printed circuit board CF may be rigid or flexible.

The printed circuit board CF may include a timing control circuit for controlling an operation of the display panel DP. The timing control circuit may be mounted on the printed circuit board CF in the form of an integrated chip. In addition, although not illustrated, the printed circuit board CF may include an input detection circuit which controls the input sensor ISU (see FIG. 2A).

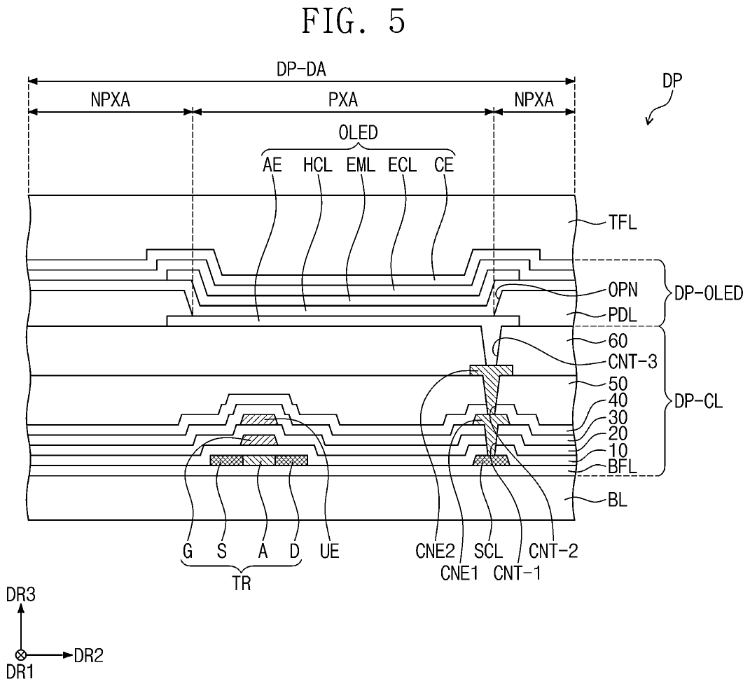

FIG. 5 is a cross-sectional view of a display panel DP according to an embodiment of the invention.

Referring to FIG. 5, a display region DP-DA may include a light-emitting region PXA and a non-light-emitting region NPXA. The pixels PX each include an organic light-emitting diode OLED as a light emitting element and a pixel driving circuit which is connected thereto. Specifically, the pixel PX may include a transistor TR and an organic light-emitting diode OLED. FIG. 5 illustrates a portion of a transistor TR in the pixel driving circuit.

The display panel DP may include a plurality of insulating layers, a semiconductor pattern, a conductive pattern, a signal line, and the like. The insulating layer, the semiconductor layer, and the conductive layer are formed through coating, deposition, and the like. Thereafter, the insulating layer, the semiconductor layer, and the conductive layer may be selectively patterned by performing a photolithography process. In this manner, the semiconductor pattern, the conductive pattern, and the signal line variously included in the circuit element layer DP-CL and the display element layer DP-OLED are formed.

A base layer BL may include a synthetic resin film. The base layer BL may have a multi-layered structure. For example, the base layer BL may have a three-layered structure of a synthetic resin layer, an inorganic layer, and a synthetic resin layer. In particular, the synthetic resin layer may be a polyimide-based resin layer, and materials thereof are not particularly limited. Additionally, the base layer BL may include a glass substrate, a metal substrate, an organic/inorganic composite material substrate, or the like.

At least one inorganic layer is disposed on an upper surface of the base layer BL. The inorganic layer may be formed as a multi-layer. The multi-layered inorganic layers may be composed of a barrier layer and/or a buffer layer BFL. In an embodiment, the display panel DP is illustrated to include a buffer layer BFL.

A semiconductor pattern is disposed on the buffer layer BFL. The semiconductor pattern may include polysilicon. However, the semiconductor pattern is not limited thereto, and may include amorphous silicon, or a metal oxide.

FIG. 5 illustrates a portion of a semiconductor pattern of a semiconductor layer but a semiconductor pattern of the semiconductor layer may be further disposed in another region of the pixel PX on a plane. The semiconductor pattern may be arranged across pixels PX in accordance with the specific rule. The electrical properties of the semiconductor pattern varies depending on whether an area thereof is doped or not. The semiconductor pattern may include a first region and a second region. The first region may be doped with an N-type dopant or a P-type dopant. A P-type transistor includes a doped region doped with a P-type dopant.

The first region has higher conductivity (e.g., electrical conductivity) than the second region and substantially serves as an electrode or a signal line. The second region may have a lower doping concentration, or may be an undoped region. Substantially, the second region corresponds to an active region (or channel) of a transistor TR. That is, a portion of the semiconductor pattern may be an active A of a transistor TR, another portion may be a source S or drain D of a transistor TR, and still another portion may be a connection electrode or connection signal line SCL.

As illustrated in FIG. 5, a source S, an active A, and a drain D of the transistor TR are formed from a single semiconductor pattern.

FIG. 5 illustrates a portion of a connection signal line SCL formed from the semiconductor layer in which the semiconductor pattern is disposed. Although not illustrated separately, the connection signal line SCL may be electrically connected, on a plane, to the drain D of the transistor TR. Another transistor TR may be disposed between the connection signal line SCL and the drain D of the transistor TR.

A first insulating layer 10 is disposed on the buffer layer BFL. The first insulating layer 10 overlaps a plurality of pixels PX in common and covers the semiconductor pattern. The gate G is disposed on the first insulating layer 10. The gate G may be a portion of a metal pattern in a first conductive layer. The gate G overlaps the active A. During the process of doping the semiconductor pattern, the gate G functions as a mask.

A second insulating layer 20 covering the gate G is disposed on the first insulating layer 10. The second insulating layer 20 overlaps the pixels PX in common. An upper electrode UE may be disposed on the second insulating layer 20. The upper electrode UE may overlap the gate G of the transistor TR. The upper electrode UE may be a portion of a metal pattern in a second conductive layer. A portion of the gate G and the upper electrode UE overlapping the portion may together define a capacitor.

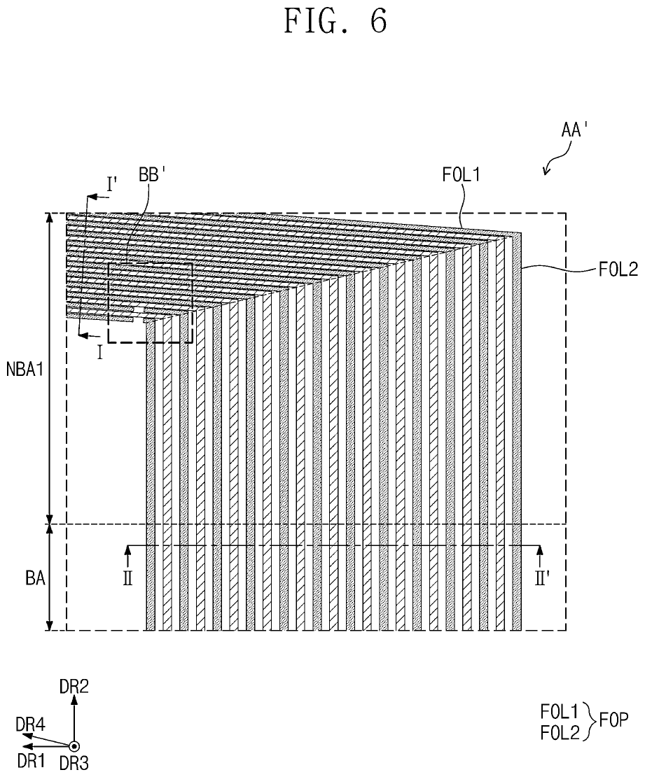

Although not illustrated, a first gate wire formed from the same process as the gate G, and a second gate wire formed from the same process as the upper electrode UE may be defined. The first gate wire and the second gate wire may together be a partial configuration of a fanout wiring part FOP (see FIG. 6) to be described later. As being provided in a same process, elements may be in a same layer as each other and/or include a same material as each other, elements may be respective portions of a same material layer, elements may be on a same layer by forming an interface with a same underlying or overlying layer, etc., without being limited thereto.

A third insulating layer 30 covering the upper electrode UE is disposed on the second insulating layer 20. A first connection electrode CNE1 disposed on the third insulating layer 30 may be connected to a connection signal line SCL via or at a first contact hole CNT-1 passing through the first to third insulating layers 10 to 30. That is, an insulating layer may define a contact hole therein. One or more of the insulating layers described herein may constitute “an insulating layer,” without being limited thereto.

A fourth insulating layer 40 covering the first connection electrode CNE1 is disposed on the third insulating layer 30. The first insulating layer 10 to the fourth insulating layer 40 may each be an inorganic layer and/or an organic layer, and have a single- or multi-layered structure.

A fifth insulating layer 50 is disposed on the fourth insulating layer 40. The fifth insulating layer 50 may be an organic layer. A second connection electrode CNE2 may be disposed on the fifth insulating layer 50. The second connection electrode CNE2 may be connected to the first connection electrode CNE1 via or at a second contact hole CNT-2 passing through the fourth insulating layer 40 and the fifth insulating layer 50.

A sixth insulating layer 60 covering the second connection electrode CNE2 is disposed on the fifth insulating layer 50. The sixth insulating layer 60 may be an organic layer. A first electrode AE is disposed on the sixth insulating layer 60. The first electrode AE is connected to the second connection electrode CNE2 via or at a third contact hole CNT-3 passing through the sixth insulating layer 60.

A pixel opening OPN is defined in a pixel-defining film PDL. The pixel opening OPN of the pixel-defining film PDL exposes at least a portion of the first electrode AE to outside the pixel-defining film PDL. In this embodiment, the light-emitting region PXA is defined to correspond to a partial region of the first electrode AE which is exposed by the pixel opening OPN. That is, a planar area of the light-emitting region PXA may correspond or be defined by a planar area of the pixel opening OPN, such as along the DR1-DR2 plane.

A hole control layer HCL may be disposed in a light-emitting region PXA and a non-light-emitting region NPXA in common. The hole control layer HCL may include a hole transport layer, and further include a hole injection layer. A light-emitting layer EML is disposed on the hole control layer HCL. The light-emitting layer EML may be disposed in a region corresponding to the pixel opening OPN. That is, the light-emitting layer EML may be formed separately in each of the pixels PX. However, an embodiment of the invention is not limited thereto, and the light-emitting layer EML may be formed, in common, in a plurality of pixels PX by using an open mask.

An electron control layer ECL is disposed on the light-emitting layer EML. The electron control layer ECL may include an electron transport layer and further include an electron injection layer. The hole control layer HCL and the electron control layer ECL may be formed, in common, in a plurality of pixels PX by using an open mask. A second electrode CE is disposed on the electron control layer ECL, facing the first electrode AE. The second electrode CE has an integrated shape (e.g., a single body or unitary body) and is disposed, in common, in the plurality of pixels PX (see FIG. 4). An upper insulating layer TFL is disposed on the second electrode CE. The upper insulating layer TFL may include a plurality of thin films.

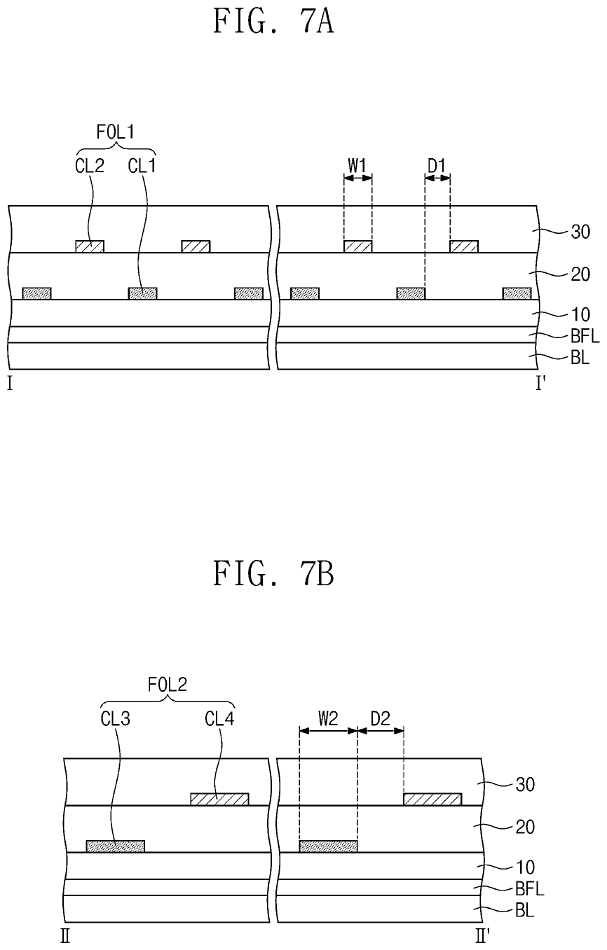

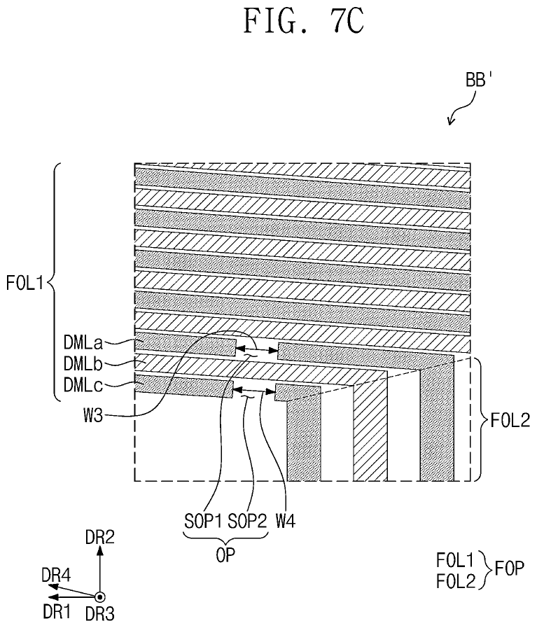

FIG. 6 is an enlarged view of region AA′ illustrated in FIG. 4. FIG. 7A is a cross-sectional view taken along line I-I′ illustrated in FIG. 6. FIG. 7B is a cross-sectional view taken along line II-II′ illustrated in FIG. 6. Specifically, FIG. 6 is a view of a portion of the fanout wiring part FOP illustrated in FIG. 4, FIG. 7A is a cross-sectional view of a plurality of first fanout wires FOL1, and FIG. 7B is a cross-sectional view of a plurality of second fanout wires FOL2. FIG. 7C is an enlarged view of region BB′ of FIG. 6.

Referring to FIG. 6, the fanout wiring part FOP may include the plurality of first fanout wires FOL1 and the plurality of second fanout wires FOL2 which extend from ends of (e.g., virtual ends of) the plurality of first fanout wires FOLL.

Referring to FIGS. 4 and 6, the plurality of first fanout wires FOL1 may be wires extending from signal lines SGL. That is, fanout wires may be connected to various signal lines, at the first fanout wires FOLL. For example, the plurality of first fanout wires FOL1 may be wires extending from data lines DL among the signal lines SGL, such that fanout wires are connected to the data lines DL at the first fanout wires FOLL. The plurality of first fanout wires FOL1 may extend in an oblique direction DR4 with respect to the first direction DR1 and the second direction DR2. The oblique direction DR4 as an incline direction may be a direction more biased toward the first direction DR1 (e.g., closer to the first direction DR1 than the second direction DR2). The plurality of second fanout wires FOL2 may extend from virtual ends of the plurality of first fanout wires FOLL. The plurality of second fanout wires FOL2 may extend to be parallel to the second direction DR2 and may be arranged in (or along) the first direction DR1. A boundary between the first fanout wires FOL1 and the second fanout wires FOL2 may be defined where an extension direction of the first fanout wires FOL1 (e.g., along the inclined direction) changes, such as to an extension direction of the second fanout wires FOL2 (e.g., along the second direction DR2)

A non-display region DP-NDA may include a bending region BA. According to an embodiment of the invention, the plurality of first fanout wires FOL1 may be disposed in a non-bending region which is between the bending region BA of the non-display region DP-NDA, and the display region DP-DA. The plurality of second fanout wires FOL2 may extend from the non-bending region and into the bending region BA to overlap the bending region BA of the non-display region DP-NDA.

Referring to FIGS. 6 and 7A, the plurality of first fanout wires FOL1 may include a plurality of first connection wires CL1 in a first connection wire layer, and a plurality of second connection wires CL2 in a second connection wire layer which are alternately disposed on a plane (e.g., in a plan view, along the third direction DR3). According to an embodiment of the invention, a layer on which the plurality of first connection wires CL1 are disposed may differ from a layer on which the plurality of second connection wires CL2 are disposed. For example, the plurality of first connection wires CL1 may be disposed on a first insulating layer 10, and the plurality of second connection wires CL2 may be disposed on a second insulating layer 20. In an embodiment, for example, first connection wires CL1 of a first conductive layer are connected to first signal lines among the signal lines SGL, and second connection wires CL2 of a second conductive layer on the first conductive layer are connected to second signal lines among the signal lines SGL.

The plurality of first connection wires CL1 may be formed from the same process as the gate G illustrated in FIG. 5. Additionally, the plurality of second connection wires CL2 may be formed from the same process as the upper electrode UE illustrated in FIG. 5. That is, the gate G and the plurality of first connection wires CL1 may be included in the first gate wire of the first conductive layer, and the upper electrode UE and the plurality of second connection wires CL2 may be included in the second gate wire of the second conductive layer.

Referring to FIGS. 6 and 7B, the plurality of second fanout wires FOL2 may include a plurality of third connection wires CL3 and a plurality of fourth connection wires CL4 which are alternately disposed on a plane. According to an embodiment of the invention, a layer on which the plurality of third connection wires CL3 are disposed may differ from a layer on which the plurality of fourth connection wires CL4 are disposed. For example, the plurality of third connection wires CL3 may be disposed on the first insulating layer 10, and the plurality of fourth connection wires CL4 may be disposed on the second insulating layer 20. The plurality of third connection wires CL3 extend from the plurality of first connection wires CL1 illustrated in FIG. 7A, and the plurality of fourth connection wires CL4 extend from the plurality of second connection wires CL2 illustrated in FIG. 7A.

The plurality of third connection wires CL3 may be formed from the same process as the gate G illustrated in FIG. 5. Additionally, the plurality of fourth connection wires CL4 may be formed from the same process as the upper electrode UE illustrated in FIG. 5. That is, the plurality of third connection wires CL3 may be included in the first gate wire of the first conductive layer, similarly to the plurality of first connection wires CL1, and the plurality of fourth connection wires CL4 may be included in the second gate wire of the second conductive layer, similarly to the second connection wires CL2.

The connection wires may have an extension direction (e.g., a major dimension) and a width which is defined normal to the extension direction. Referring to FIGS. 6 to 7B, the plurality of first connection wires CL1 and the plurality of second connection wires CL2 may have the same width as each other, and the plurality of third connection wires CL3 and the plurality of fourth connection wires CL4 may have the same width as each other. A width of each of the plurality of first connection wires CL1 and the plurality of second connection wires CL2 may be defined as a first width W1, and a width of each of the plurality of third connection wires CL3 and the plurality of fourth connection wires CL4 may be defined as a second width W2. According to an embodiment of the invention, the first width W1 and the second width W2 may differ from each other. For example, the second width W2 may be greater than the first width W1. In an embodiment, the first fanout wires FOL1 are spaced apart from each other along a first width direction (e.g., along line I-I′ in FIG. 6, for example) and each have a first width W1 along the first width direction, and the second fanout wires FOL2 are spaced apart from each other along a second width direction (e.g., along line II-II′ in FIG. 6, for example) and each have a second width W2 along the second width direction which is different from the first width W1.

Connection wires may be spaced apart from each other by an interval between closest edges of the connection wires along the width direction. Intervals D1 between the plurality of first connection wires CL1 and the plurality of second connection wires CL2 adjacent thereto may be the same, and intervals D2 between the plurality of third connection wires CL3 and the plurality of fourth connection wires CL4 adjacent thereto may be the same. The intervals D1 between the plurality of first connection wires CL1 and the plurality of second connection wires CL2 adjacent thereto may be defined as a first interval D1, and the intervals D2 between the plurality of third connection wires CL3 and the plurality of fourth connection wires CL4 adjacent thereto may be defined as a second interval D2. According to an embodiment of the invention, the first interval D1 and the second interval D2 may differ from each other. For example, the second interval D2 may be greater than the first interval D1.

Referring again to FIG. 7A, the plurality of first connection wires CL1 and the plurality of second connection wires CL2 may be disposed on different layers, may not overlap each other on a plane, and may be alternately disposed on a plane. Accordingly, the plurality of first connection wires CL1 and the plurality of second connection wires CL2 may be arranged within the same area (e.g., same planar area), and the individual width of each of the plurality of first connection wires CL1 and the plurality of second connection wires CL2 may increase. When the widths of the connection wires CL1 and CL2 increase, resistances (e.g., electrical resistances) of the connection wires CL1 and CL2 decrease, and thus the scan speed for signal lines increases. Therefore, the display device DD (see FIG. 1) may have improved operational and display quality.

Referring to FIG. 7C, fanout wires in the fanout wiring part FOP may include a plurality of connection wires CNL at which the fanout wires are connected to the signal lines SGL (see FIG. 4) such as being extended portions thereof, and first to third dummy wires DMLa, DMLb, and DMLc at which the fanout wires may not be connected to the signal lines SGL (e.g., disconnected from the signal lines SGL). Along a direction in which the fanout wires are adjacent to each other, plural dummy wires may be arranged in order, such as in a direction toward an outer edge of the display panel DP, without being limited thereto. In region AA′ of FIG. 4, the first and third dummy wires DMLa and DMLc among a series of dummy fanout wires in the fanout wiring part FOP are in order in a direction towards an outer edge of the display panel DP.

According to an embodiment of the invention, an opening OP or gap may be defined in one or more of the series of the dummy fanout wires, such as in the first and third dummy wires DMLa and DMLc. Here, the display device DD may include a display region DD-DA including pixels PX and a non-display region DD-NDA which is adjacent to the display region DD-DA, fanout lines (e.g., lines or wirings of the fanout wiring part FOP) in the non-display region DD-NDA, and signal lines SGL which are in the display region DD-DA and connect the pixels PX in the display region DD-DA to the fanout lines in the non-display region DD-NDA. The fanout lines include first fanout wires FOL1 (including CNL and DML of FIG. 4 and portions of DMLa, DMLb and DMLc of FIG. 7C) spaced apart from each other along the non-display region DD-NDA at a first interval D1 (FIG. 7A), at least one of the first fanout wires FOL1 being disconnected along a length thereof to define an opening OP of the first fanout wires FOL1 (DMLa or DMLc in FIG. 7C, for example), and second fanout wires FOL2 (including CNL and DML of FIG. 4 and portions of DMLa, DMLb and DMLc of FIG. 7C) respectively extending from the first fanout wires FOL1 and spaced apart from each other along the non-display region DD-NDA at a second interval D2 greater than the first interval D1.

Within the series of the dummy fanout wires, the opening OP or gap may be provided in plural such as including a first sub-opening SOP1 and a second sub-opening SOP2 which face each other in a width direction of the series of the dummy fanout wires, with the second dummy wire DMLb therebetween. In an embodiment the second dummy wire DMLb among the series of the dummy fanout wires may function as one of the plurality of connection wires CNL which is connected to a respective signal line. The first sub-opening SOP1 and the second sub-opening SOP2 as disconnections in respective dummy fanout wires may be respectively formed in the dummy wires DMLa and DMLc. The first sub-opening SOP1 and the second sub-opening SOP2 may be spaced apart from each other with the second dummy wire DMLb therebetween.

Among the series of the dummy fanout wires, first length W3 of the first sub-opening SOP1 may be the same as a second length W4 of the second sub-opening SOP2, along the extension direction of the respective dummy wire. For example, the first length W3 of the first sub-opening SOP1 and the second length W4 of the second sub-opening SOP2 may each be about 4 micrometers (μm) or more. Specifically, the first length W3 of the first sub-opening SOP1 and the second length W4 of the second sub-opening SOP2 may each be about 4 μm to about 6 μm.

As illustrated in FIG. 7C, the dummy wires DMLa and DMLc defining the opening OP in the series of the dummy fanout wires may be disposed in an outermost portion of the fanout wires in the fanout wiring part FOP, specifically at the first fanout wires FOLL. However, an embodiment of the invention is not limited thereto. The dummy wires DMLa and DMLc defining the opening OP in the series of the dummy fanout wires may be disposed in a center portion of the fanout wires in the fanout wiring part FOP and are not limited to this embodiment.

Referring to FIGS. 7A and 7C together, the first and third dummy wires DMLa and DMLc in the series of the dummy fanout wires may be included in the first gate wire (e.g., the first conductive layer or a lower conductive layer), and the second dummy wire DMLb in the series of the dummy fanout wires may be included in the second gate wire (e.g., second conductive layer or an upper conductive layer). That is, the first and third dummy wires DMLa and DMLc as upper dummy wires may be disposed on the second insulating layer 20, and the second dummy wire DMLb as a lower dummy wire may be disposed on the first insulating layer 10. Substantially, the plurality of connection wires CNL and the first to third dummy wires DMLa, DMLb and DMLc have the same width, both at the first fanout area (e.g., where the first fanout wires FOL1 are disposed) and at the second fanout area (e.g., where the second fanout wires FOL2 are disposed).

In an embodiment of providing the display panel DP (or the display device DD), since the plurality of connection wires CNL and the first to third dummy wires DMLa, DMLb and DMLc has the same width, widths of the plurality of connection wires CNL may be measured by measuring a width of the second dummy wire DMLb instead. That is, the widths of the plurality of connection wires CNL may be indirectly measured by measuring or determining a width of the second dummy wire DMLb, where the width of the second dummy wire DMLb represents or corresponds to the widths of the plurality of connection wires CNL.

The opening OP as a collection of sub-openings in the series of the dummy fanout wires may be defined by a disconnected length in each of the first and third dummy wires DMLa and DMLc disposed to be adjacent to the second dummy wire DMLb. Accordingly, when the width of the second dummy wire DMLb is measured (e.g., direct measurement), lower measurement interference may occur due to material (e.g., solid portion) of the first and third dummy wires DMLa and DMLc being eliminated at locations corresponding to the disconnected lengths. Thus, the width of the second dummy wire DMLb may be accurately (and directly) measured, and the widths of the plurality of connection wires CNL may be indirectly measured by directly measuring the width of the second dummy wire DMLb with minimal or no interference from a solid portion of the first and third dummy wires DMLa and DMLc at the opening OP. Therefore, the display device DD (see FIG. 1) with operation and display reliability may be provided. In this embodiment, a width of the connection wire CNL included in the second gate wire of an upper conductive layer is measured. Here, it is possible to measure the width of the connection wire CNL included in the first gate wire (e.g., a lower conductive layer) before the connection wire CNL included in the second gate wire (e.g., the upper conductive layer) is formed.

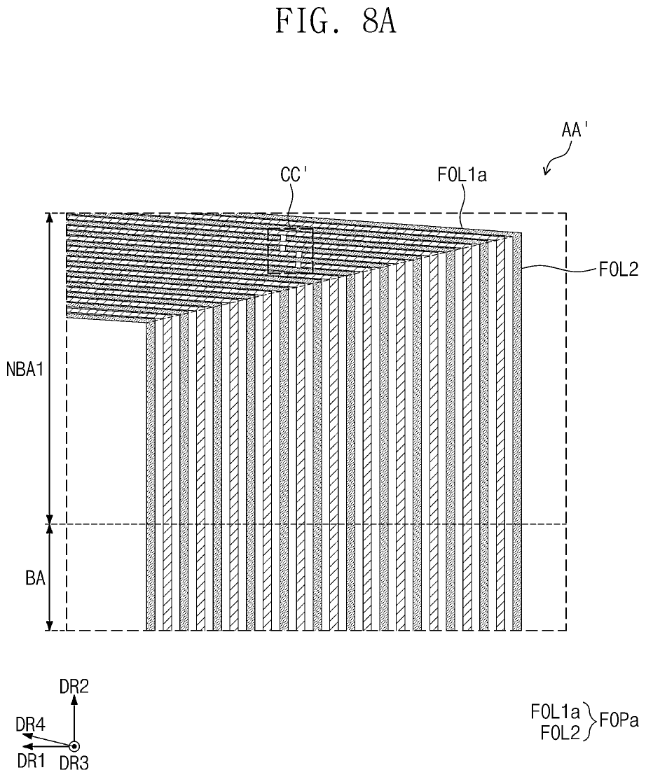

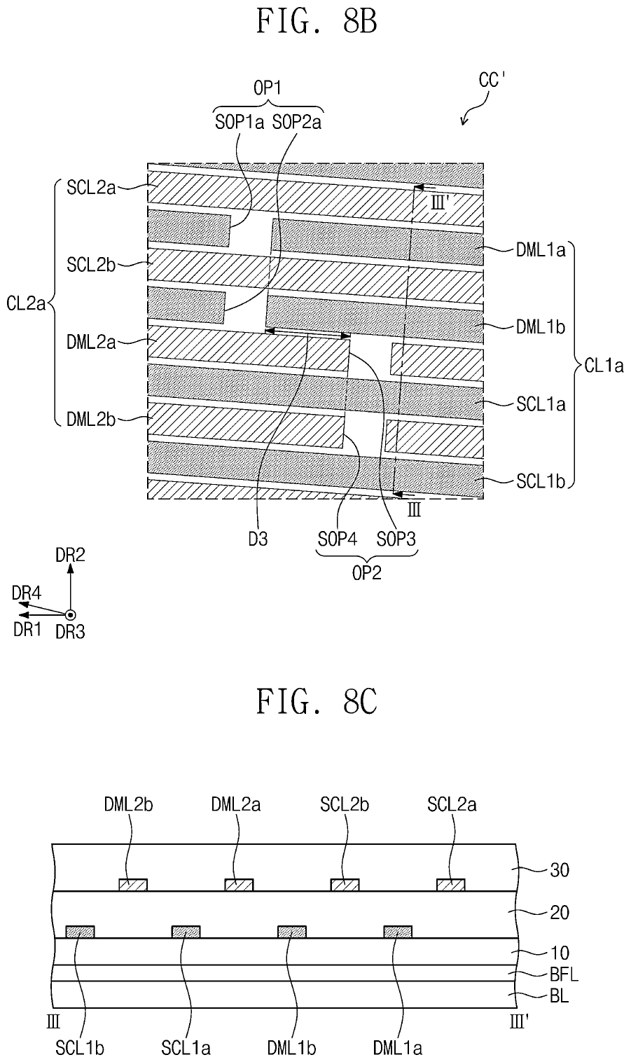

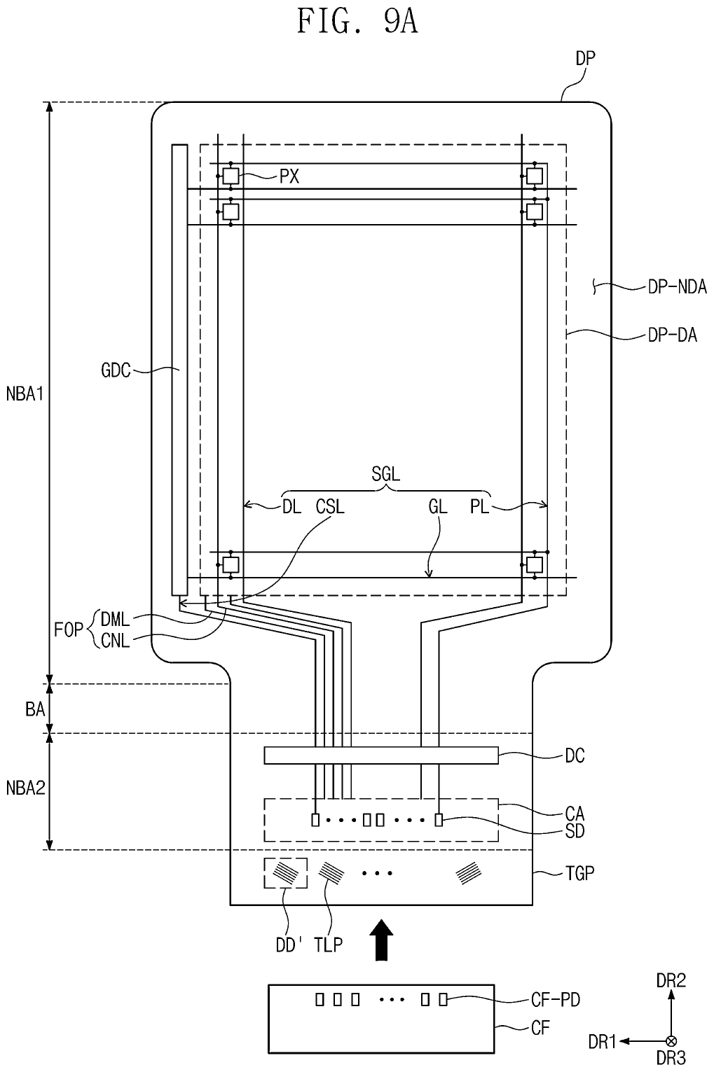

FIG. 8A is an enlarged view of a portion of a display panel DP according to an embodiment of the invention. FIG. 8B is an enlarged view of region CC′ of FIG. 8A. FIG. 8C is a cross-sectional view taken along line III-III′ illustrated in FIG. 8B. FIG. 8A is an enlarged view of region AA′ of FIG. 4 according to another embodiment.

Referring to FIGS. 8A to 8C, a plurality of first fanout wires FOL1a of a series of fanout wires FOPa may include a plurality of first connection wires CL1a and a plurality of second connection wires CL2a which are alternately disposed on a plane. Within the series of fanout lines including the first connection wires CL1a and the second connection wires CL2a, there is a series of dummy wires and a series of sub-connection wires which alternate with each other along a width direction of the fanout lines.

The plurality of first connection wires CL1a may include a plurality of first sub-connection wires SCL1a and SCL1b connected to a portion of the signal lines SGL (see FIG. 4), and a plurality of first dummy wires DML1a and DML1b not connected to the signal lines SGL. The plurality of first sub-connection wires SCL1a and SCL1b, and the plurality of first dummy wires DML1a and DML1b may be disposed on a first insulating layer 10, and be included in the first gate wire of a lower conductive layer.

The plurality of second connection wires CL2a may include a plurality of second sub-connection wires SCL2a and SCL2b connected to a portion of the signal lines SGL and a plurality of second dummy wires DML2a and DML2b not connected to the signal lines SGL. The plurality of second sub-connection wires SCL2a and SCL2b and the plurality of second dummy wires DML2a and DML2b may be disposed on a second insulating layer 20, and be included in the second gate wire of an upper conductive layer.

According to an embodiment of the invention, a first opening OP1 may be formed in a collection of the first dummy wires DML1a and DML1b, and a second opening OP2 may be formed in a collection of the second dummy wires DML2a and DML2b. The first opening OP1 and the second opening OP2 may not overlap each other on a plane.

The first opening OP1 may include a first sub-opening SOP1a and a second sub-opening SOP2a which are respectively formed in the first dummy wires DML1a and DML1b. The first sub-opening SOP1a and the second sub-opening SOP2a may face each other with the second sub-connection wire SCL2b therebetween (e.g., a first group of dummy wires). For example, the first sub-opening SOP1a and the second sub-opening SOP2a may be disposed to be spaced apart from each other with the second sub-connection wire SCL2b therebetween.

The second opening OP2 may include a third sub-opening SOP3 and a fourth sub-opening SOP4 which are respectively formed in the second dummy wires DML2a and DML2b. The third sub-opening SOP3 and the fourth sub-opening SOP4 may face each other with the first sub-connection wire SCL1a therebetween (e.g., a second group of dummy wires). For example, the third sub-opening SOP3 and the fourth sub-opening SOP4 may be disposed to be spaced apart from each other with the first sub-connection wire SCL1a therebetween.

In one or more embodiment, dummy wires which are on opposing sides of a target dummy wire to be measured or inspected have a disconnected length respectively defined therein. FIG. 7C illustrates the disconnected dummy wires in a same wire layer (e.g., the first and third dummy wires DMLa and DMLc in the first gate wire (e.g., the first conductive layer or a lower conductive layer). FIGS. 8B and 8C illustrate disconnected dummy wires in both wire layers (e.g., the first dummy wires DML1a and DML1b in the first gate wire of a lower conductive layer and the second dummy wires DML2a and DML2b in the second gate wire of an upper conductive layer).

The first opening OP1 and the second opening OP2 may be disposed to be spaced apart from each other in the fourth direction DR4. Specifically, the second sub-opening SOP2a and the third sub-opening SOP3 may be disposed to be spaced apart from each other in the fourth direction DR4. For example, the second sub-opening SOP2a and the third sub-opening SOP3 may be spaced apart from each other in the fourth direction DR4 (or along an extension direction of a fanout line) at an interval D3 of about 8 μm to about 10 μm. Since the second sub-opening SOP2a and the third sub-opening SOP3 are formed to be spaced apart from each other in the fourth direction DR4 at an interval D3 of about 8 μm to about 10 μm, widths of the second sub-connection wire SCL2b and the first sub-connection wire SCL1a may be measured together with each other through a single inspection process, and thus inspection efficiency of the series of fanout lines may be enhanced.

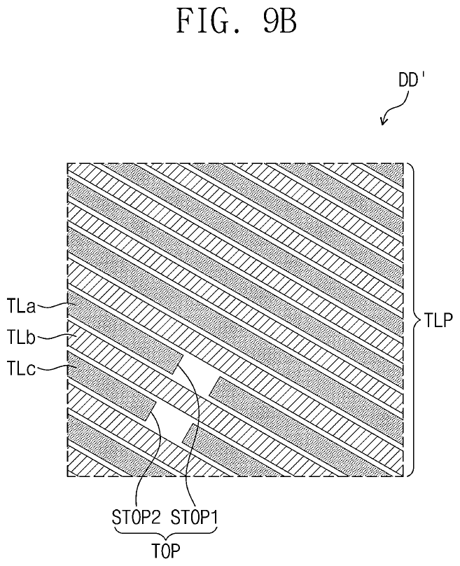

FIG. 9A is a view illustrating a display panel DP and a tag part TGP according to an embodiment of the invention. FIG. 9B is an enlarged view of region DD′ illustrated in FIG. 9A.

Referring to FIG. 9A, a tag part TGP may be disposed on a lower side of a display panel DP, that is, at a distal end portion thereof. Specifically, the tag part TGP may be disposed adjacent to a second non-bending region NBA2 of the display panel DP. A tag wire part TLP may be disposed in the tag part TGP. The tag part TGP is provided to inspect the display panel DP according to the invention. The tag part TGP with which a preliminary form of the display panel DP is inspected, may be cut or separated from the preliminary form of the display panel DP after the inspection of structures within the preliminary form of the display panel DP is completed.

In one or more embodiment, the opening OP in the fanout wiring part FOP illustrated in FIG. 7C may not be defined in the fanout wiring part FOP illustrated in FIG. 9A. Instead, the tag wire part TLP illustrated in FIG. 9A may be used to indirectly measure a width of the first fanout wire FOL1 of the fanout wiring part FOP illustrated in FIG. 6 similar to how the opening OP in the fanout wiring part FOP illustrated in FIG. 7C may be used to indirectly measure a width of the first fanout wire FOL1 of the fanout wiring part FOP illustrated in FIG. 6.

Referring to FIG. 9B, the tag wire part TLP may include a plurality of tag wires TLP. A tag opening TOP may be defined in a portion of the plurality of tag wires TLP. For convenience of description, three tag wires among the plurality of tag wires TLP are respectively referred to as first to third tag wires TLa, TLb, and TLc and form a series of the tag wires TLP. As illustrated in FIG. 9A, the tag wires TLP may be a discrete pattern having an island shape in the tag line area (e.g., the tag part TGP).

A width of each of the first to third tag wires TLa, TLb, and TLc and a distance between the first to third tag wires TLa, TLb, and TLc may be the same as a width of each of the first fanout wires FOL1 and a distance between the first fanout wires FOL1, which illustrated in FIG. 8A. The first and third tag wires TLa and TLc are disposed on the same layer as the plurality of first connection wires CL1 of FIG. 7A (e.g., the first wire as a lower wire layer), and the second tag wire TLb is disposed on the same layer as the plurality of second connection wires CL2 of FIG. 7A (e.g., the second wire as an upper wire layer).

The tag opening TOP may include a first sub-tag opening STOP1 and a second sub-tag opening STOP2 which are respectively formed in the first and third tag wires TLa and TLc. When a width of the second tag wire TLb is directly measured, the first sub-tag opening STOP1 and the second sub-tag opening STOP2 are respectively formed in the first and third tag wires TLa and TLc on opposing sides of the target wire to be measured (e.g., the second tag wire TLb). Thus, direct measurement of a width of the second tag wire TLb between the first sub-tag opening STOP1 and the second sub-tag opening STOP2 may be accurately measured. That is, a width of the plurality of first fanout wires FOL1 illustrated in FIG. 8A may be indirectly measured by measuring a width of the second tag wire TLb as an inspection wire. That is, the width of the inspection wire as the second tag wire TLb, represents or corresponds to width of the plurality of first fanout wires FOL1 illustrated in FIG. 8A.

A display device DD according to an embodiment of the invention may include a fanout wire disposed on a non-display region DD-DA. The fanout wire may include a connection wire connected to a signal line, and a dummy wire which is not connected to the signal line and adjacent to the connection wire. When a width of the connection wire as an inspection target is measured (e.g., directly measured), an opening or gap may be defined in a dummy wire which is adjacent to the connection wire to be measured. Measurement of the inspection target may be performed at a location of the target wire which is closest to the gap in the dummy wire. Accordingly, interference which may occur due to a material portion of dummy wires disposed adjacent to the connection wire of which a width is to be directly measured, is eliminated, a width of the connection wire as the inspection target may be accurately measured. Thus, a display device DD with reliability may be provided.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention is not limited to the contents described in the detailed description of the specification, but should be determined by the claims.

What is claimed is:

1. A display device comprising:
a display region including pixels and a non-display region which is adjacent to the display region;
fanout lines in the non-display region; and
signal lines which are in the display region and connect the pixels in the display region to the fanout lines in the non-display region,
wherein the fanout lines comprise:
first fanout wires spaced apart from each other along the non-display region at a first interval,
at least one of the first fanout wires being disconnected along a length thereof to define an opening of the first fanout wires, and
second fanout wires respectively extending from the first fanout wires and spaced apart from each other along the non-display region at a second interval greater than the first interval.

2. The display device of claim 1, wherein the first fanout wires comprise:
a connection wire connected to a signal line among the signal lines; and
a dummy wire which is adjacent to the connection wire and not connected to the signal lines.

3. The display device of claim 2, wherein the dummy wire is disconnected along a length thereof to define the opening of the first fanout wires.

4. The display device of claim 3, wherein among the first fanout wires in the non-display region, the dummy wire which defines the opening is an outermost first fanout wire.

5. The display device of claim 1, wherein within the non-display region, the first fanout wires comprise:
first connection wires and second connection wires alternating with each other, and
the first connection wires and the second connection wires in different layers from each other along a thickness direction of the non-display region.

6. The display device of claim 5, further comprising:
a base layer in the display region and in the non-display region, and
a first insulating layer and a second insulating layer on the base layer,
wherein the base layer, the first insulating layer, the first connection wires, the second insulating layer and the second connection wires are in order along the thickness direction of the non-display region.

7. The display device of claim 5, wherein
the first connection wires comprise:
a first sub-connection wire connected to a first signal line among the signal lines, and
a first dummy wire which is adjacent to the first sub-connection wire and not connected to the signal lines, and
the second connection wires comprise:
a second sub-connection wire connected to a second signal line among the signal lines, and
a second dummy wire which is adjacent to the second sub-connection wire and not connected to the signal lines.

8. The display device of claim 7, wherein
within the non-display region, the opening is provided in plural including openings of the first fanout wires;
the first dummy wire is disconnected along a length thereof to define a first opening among the openings of the first fanout wires; and
the second dummy wire is disconnected along a length thereof to define a second opening among the openings of the first fanout wires.

9. The display device of claim 8, wherein
a width direction of the first fanout wires crosses the lengths of the first dummy wire and the second dummy wire, and
the first opening does not overlap the second opening along the width direction.

10. The display device of claim 8, wherein
a width direction of the first fanout wires crosses the lengths of the first dummy wire and the second dummy wire,
the first dummy wire is provided in plural including first dummy wires on opposing sides of the first sub-connection wire along the width direction, and
the first opening is defined in each of the first dummy wires, the first openings overlapping along the width direction with the first sub-connection wire therebetween.

11. The display device of claim 8, wherein
a width direction of the first fanout wires crosses the lengths of the first dummy wire and the second dummy wire,
the second dummy wire is provided in plural including second dummy wires on opposing sides of the second sub-connection wire along the width direction, and
the second opening is defined in each of the second dummy wires, the second openings overlapping along the width direction with the second sub-connection wire therebetween.

12. The display device of claim 1, wherein
the first fanout wires are spaced apart from each other along a first width direction and each have a first width along the first width direction, and
the second fanout wires are spaced apart from each other along a second width direction and each have a second width along the second width direction which is different from the first width.

13. The display device of claim 12, wherein
the first width and the second width are respectively constant along respective lengths of the first fanout wires and the second fanout wires, and
the second width of the second fanout wires is greater than the first width of the first fanout wires.

14. The display device of claim 1, wherein
the non-display region comprises a bending region at which the display device is bendable,
the first fanout wires are between the bending region and the display region, and
the second fanout wires are on the bending region.

15. A display device comprising:
a display region including pixels and a non-display region which is adjacent to the display region;
fanout lines in the non-display region; and
signal lines which are in the display region and connect the pixels in the display region to the fanout lines in the non-display region,
wherein the fanout lines comprise:
first connection wires of a first conductive layer which are connected to first signal lines among the signal lines,
second connection wires of a second conductive layer on the first conductive layer, the second connection wires connected to second signal lines among the signal lines, and
a connection wire among the first connection wires and the second connection wires being disconnected along a length thereof to define an opening of the fanout lines.

16. The display device of claim 15, wherein along the non-display region, the first connection wires and the second connection wires alternate with each other and are spaced apart from each other.

17. The display device of claim 15, wherein
the first connection wires comprise:
first sub-connection wires connected to the first signal lines, and
first dummy wires not connected to the signal lines, and
the second connection wires comprise:
second sub-connection wires connected to the second signal lines, and
second dummy wires not connected to the signal lines.

18. The display device of claim 17, wherein
within the non-display region, the opening is provided in plural including openings of the fanout lines;
a first connection wire is disconnected along a length thereof to define a first opening among the openings of the fanout lines; and
a second connection wire is disconnected along a length thereof to define a second opening among the openings of the fanout lines.

19. The display device of claim 15, wherein
the fanout lines comprise:
first fanout wires spaced apart from each other along the non-display region, at a first interval, and
second fanout wires respectively extending from the first fanout wires and spaced apart from each other along the non-display region, at a second interval greater than the first interval, and
at least one of the first fanout wires is disconnected along a length thereof to define the opening of the fanout lines.

20. The display device of claim 19, wherein
the non-display region comprises a bending region at which the display device is bendable,
the first fanout wires are between the bending region and the display region, and
the second fanout wires are on the bending region.
